(19) United States
(12) Patent Application Publication
(10) Pub. No.: US 2025/0038016 A1
(43) Pub. Date: Jan. 30, 2025

(54) SUBSTRATE PROCESSING APPARATUS AND SUBSTRATE PROCESSING METHOD

(71) Applicant: AP SYSTEMS INC., Hwaseong-Si, Gyeonggi-Do (KR)

(72) Inventors: Dae Ryong LEE, Hwaseong-si, Gyeonggi-do (KR); Sang Hyun JI, Yongin-si, Gyeonggi-do (KR); Chang Kyo KIM, Hwaseong-si, Gyeonggi-do (KR)

(21) Appl. No.: 18/707,165

(22) PCT Filed: Sep. 28, 2022
(86) PCT No.: PCT/KR2022/014545

§ 371 Date: May 2, 2024

(30) Foreign Application Priority Data
Nov. 11, 2021 (KR) 10-2021-0154926

(51) Int. Cl. H01L 21/67; H01L 21/268; H01L 21/66

(52) U.S. Cl. CPC H01L 21/67115; H01L 21/268; H01L 21/67248; H01L 22/12

(57) ABSTRACT

The present inventive concept relates to a substrate processing apparatus and a substrate processing method, which can accurately measure temperature in even a low-temperature region, thus making it possible to efficiently manage heat. The substrate processing apparatus comprises: a chamber for providing a processing space in which a substrate is processed; a substrate support provided in the processing space of the chamber in order to support the substrate; a heater provided with a plurality of semiconductor laser modules that emit light toward a first surface of the substrate; and a pyrometer which is provided on the side of a second surface of the substrate facing the first surface and detects light emitted from the substrate to measure the temperature of the substrate. The main light-emitting wavelength of the plurality of semiconductor laser modules may be shorter than the measurement wavelength of the pyrometer.

### TECHNICAL FIELD

The present disclosure relates to a substrate processing apparatus and a substrate processing method, and more particularly, to a substrate processing apparatus and a substrate processing method, which are capable of accurately measuring a temperature even in a low-temperature region for an efficient thermal management.

### BACKGROUND ART

In general, a semiconductor device is manufactured by repeating a unit process of processing a substrate, such as ion implantation, thin film deposition, and thermal processing, several times. In these unit processes, it is necessary to process the substrate at a predetermined process temperature by supplying thermal energy. Particularly, when light energy is used to heat the substrate up to the predetermined process temperature, since the heating process is performed for a short time, side effects of generating impurities may be minimized and thus be widely used.

In a general substrate processing apparatus, thermal processing is performed through a plurality of halogen lamps (radiation wavelength: approximately 0.4 μm to approximately 6.0 μm) in a state in which the substrate is seated in a chamber, and a temperature of the substrate is measured through a temperature measuring device such as a pyrometer in a non-contact manner. The pyrometer concentrates radiant energy emitted from the substrate to measure the temperature of the substrate in the non-contact manner, based on a blackbody radiation temperature relationship. The temperature measured by the temperature measuring device is fed back to the heating lamp through a heating controller to control a temperature of the heating lamp.

The pyrometer measures the temperature using a wavelength band of approximately 0.9 μm to approximately 1.0 μm, and a temperature measurement region range of approximately 400° C. to approximately 1,150° C. However, light transmittance of the substrate, which is measured by the pyrometer using the wavelength band of approximately 0.9 μm to approximately 1.0 μm has characteristics depending on the temperature of the substrate. For example, in case of a silicon wafer, the silicon wafer has light transmittance in a translucent state at a temperature of approximately 600° C. or less. That is, the silicon wafer has a characteristic of transmitting light in a low-temperature region due to material characteristics thereof, and thus, when the substrate has a temperature of approximately 600° C. or less, a portion of light of the halogen lamp is transmitted through the substrate. Accordingly, in the case of the low-temperature substrate, a portion of the light of the halogen lamp having a radiation wavelength of approximately 0.4 μm to approximately 6.0 μm is transmitted through the substrate. As a result, the pyrometer having a measurement wavelength band of approximately 0.9 μm to approximately 1.0 μm may measure the transmitted light, and thus, the temperature of only the substrate may not be accurately measured, and a temperature measurement error may occur. That is, when the temperature of the substrate is approximately 600° C. or less, not only an amount of light generated from the substrate itself, but also an amount of light emitted from the halogen lamp passing through the substrate may be added to be measured by the temperature measuring device. When the temperature of the substrate is approximately 600° C. or less, the temperature measured from the pyrometer may be fed back to the heating controller to control the temperature, and the heating controller may heat the substrate by applying an arbitrary output to the heating lamp. Here, non-uniformity of the temperature of the substrate may occur, resulting in bending or cracking of the substrate.

### Prior Art Document

(Patent Document 1) Korean Patent No. 10-0974013

### DISCLOSURE OF THE INVENTIVE CONCEPT

### Technical Problem

The present disclosure provides a substrate processing apparatus and a substrate processing method, which are capable of accurately measuring a temperature even in a low-temperature region to realize efficient thermal management.

The present disclosure also provides a substrate processing apparatus and a substrate processing method, which are capable of accurately measuring a temperature even in a low-temperature region to realize highly reliable substrate processing in the low-temperature region.

### Technical Solution

In accordance with an exemplary embodiment, a substrate processing apparatus includes: a chamber configured to provide a processing space in which a substrate is processed; a substrate support provided in the processing space of the chamber to support the substrate; a heater provided with a plurality of semiconductor laser modules configured to irradiate light toward a first face of the substrate; and a pyrometer provided at a side of a second face facing the first face to detect light incident from the substrate, thereby measuring a temperature, wherein a main emission wavelength of the plurality of semiconductor laser modules is less than a measurement wavelength of the pyrometer.

A temperature at which the substrate is processed may include a temperature range of approximately 600° C. or less.

Each of the semiconductor laser modules may include a vertical cavity surface emitting laser.

The plurality of semiconductor laser modules may include: a central semiconductor laser module provided at a central portion of the heater; and a peripheral semiconductor laser module provided around the central semiconductor laser module.

Each of the plurality of semiconductor laser modules may have an edge having a polygonal shape.

The substrate processing apparatus may further include a reflector configured to surround an edge of each of the plurality of semiconductor laser modules to reflect at least a portion of light emitted from the plurality of semiconductor laser modules toward the substrate.

The reflector may include an inclined reflective surface having an inclined angle of approximately 80 degrees to approximately 90 degrees with respect to an emission surface of each of the plurality of semiconductor laser modules.

A metal reflective film may be coated on the inclined reflective surface.

Each of the plurality of semiconductor laser modules may be divided into a first area and a second area, wherein the plurality of first areas and the plurality of second areas are electrically connected for each area, and the substrate processing apparatus may further include a first power supply and a second power supply, which independently apply power applied respectively for each area to the plurality of first areas electrically connected to each other and the plurality of second areas electrically connected to each other.

The pyrometer may include: a first pyrometer provided to correspond to the first area; and a second pyrometer provided to correspond to the second area, wherein the first power supply and the second power supply may apply the power to the plurality of semiconductor modules for each area using temperatures measured by the first pyrometer and the second pyrometer.

The plurality of semiconductor laser modules may be arranged so that at least one virtual circle using a central portion of the heater as a center crosses either one of the first area and the second area.

In accordance with another exemplary embodiment, a substrate processing method include: providing a substrate in a processing space of a chamber; irradiating light onto a first face of the substrate by using a plurality of semiconductor laser modules provided in a heater; and measuring a temperature of the substrate by using a pyrometer provided at a side of a second face of the substrate, which faces the first face, wherein a main emission wavelength of the plurality of semiconductor laser modules is less than a measurement wavelength of the pyrometer.

A temperature at which the substrate is processed may include a temperature range of approximately 600° C. or less.

Each of the semiconductor laser modules may include a vertical cavity surface emitting laser.

Each of the plurality of semiconductor laser modules may be divided into a first area and a second area, wherein the plurality of first areas and the plurality of second areas may be electrically connected for each area, and the irradiating of the light may include applying power independently for each area to the plurality of first areas electrically connected to each other and the plurality of second areas electrically connected to each other.

The pyrometer may include: a first pyrometer provided to correspond to the first area; and a second pyrometer provided to correspond to the second area, wherein the measuring of the temperature may include measuring a temperature for each area on areas of the substrate, which correspond to the first area and the second area, by using the first pyrometer and the second pyrometer, and in the applying of the power, the power may be independently applied for each area by using the measured temperature for each area.

The plurality of semiconductor laser modules may be arranged so that at least one virtual circle using a central portion of the heater as a center crosses either one of the first area and the second area.

### Advantageous Effects

In the substrate processing apparatus and the substrate processing method in accordance with the exemplary embodiments, since the light energy is supplied using the semiconductor laser module having the main emission wavelength band that is different from the measurement wavelength band of the pyrometer, the temperature of the substrate may be accurately measured and controlled even in the low-temperature region of approximately 600° C. or less.

That is, in the apparatus and method for measuring the temperature of the substrate in accordance with the exemplary embodiments, the temperature of the substrate may be accurately calculated in the low-temperature region of approximately 600° C. or less, and the power applied to the heater may be controlled based on the calculated temperature of the substrate to accurately control the temperature of the substrate even in the low-temperature region. In addition, the temperature uniformity of the substrate may be secured to prevent the substrate from being damaged and secure the reliability of the low-temperature process of approximately 600° C. or less.

When the vertical cavity surface emitting laser is used as the light source, the power consumption may be reduced compared to the typical halogen lamp due to the high energy efficiency, and the light characteristics may be effectively controlled due to the straightness of the light source and the easy emission of the light having the specific wavelength.

In addition, the semiconductor laser module may be divided into the plurality of areas and arranged in the various types of arrays, and the input power may be controlled for each area to improve the uniformity of the temperature control of the substrate.

### BRIEF DESCRIPTION OF THE DRAWINGS

FIG. 1 is a view illustrating a configuration of a substrate processing apparatus in accordance with an exemplary embodiment.

FIG. 2 is a view for explaining a structure of a heater in accordance with an exemplary embodiment.

FIG. 3 is a view illustrating various shapes of an arrangement of semiconductor laser modules in accordance with an exemplary embodiment.

FIG. 4 is a view illustrating an effect of temperature uniformity of the substrate processing apparatus in accordance with an exemplary embodiment.

FIG. 5 is a view illustrating a reflector in accordance with an exemplary embodiment.

FIG. 6 is a view for explaining a manner for controlling the semiconductor laser module in accordance with an exemplary embodiment.

FIG. 7 is a view for explaining a manner for arranging the semiconductor laser module in accordance with an exemplary embodiment.

FIG. 8 is a flowchart illustrating a substrate processing method in accordance with another exemplary embodiment.

### MODE FOR CARRYING OUT THE INVENTIVE CONCEPT

Hereinafter, specific embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the descriptions, the same elements are denoted with the same reference numerals. In the figures, the dimensions of layers and regions are exaggerated for clarity of illustration. Like reference numerals refer to like elements throughout.

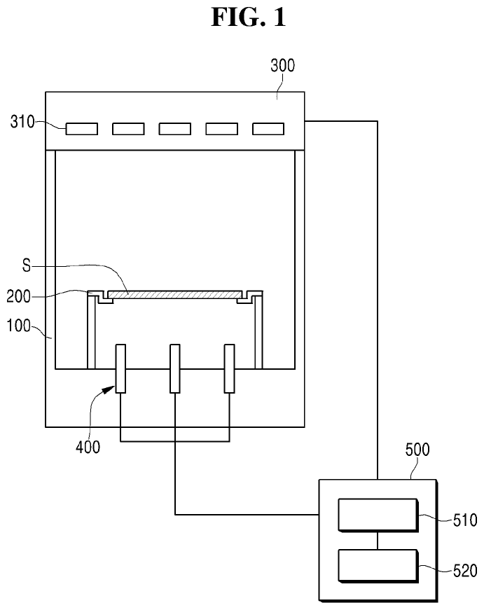

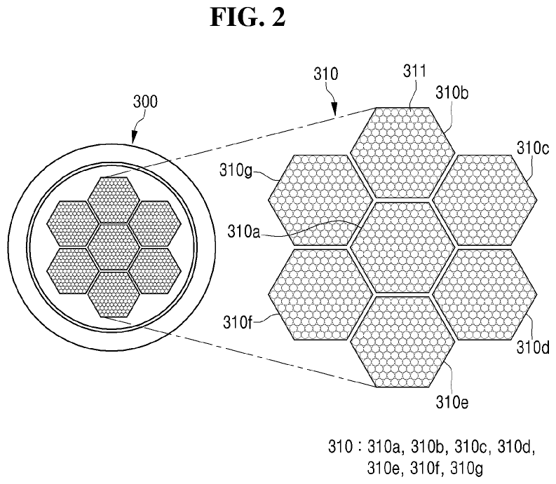

FIG. 1 is a view illustrating a configuration of a substrate processing apparatus in accordance with an exemplary embodiment, and FIG. 2 is a view for explaining a structure of a heater in accordance with an exemplary embodiment.

Referring to FIGS. 1 and 2, a substrate processing apparatus in accordance with an exemplary embodiment may include a chamber 100 providing a space in which a substrate S is processed, a substrate support 200 provided in the processing space of the chamber 100 to support the substrate S, a heater 300 provided with a plurality of semiconductor laser modules 310 that emit light toward a first face of the substrate S, and a pyrometer 400 provided at a side of a second face of the substrate S, which faces the first face, to detect light incident from the substrate, thereby measuring a temperature. Here, a main emission wavelength of the plurality of semiconductor laser modules 310 may be less than a measurement wavelength of the pyrometer 400.

A substrate processing apparatus in accordance with an exemplary embodiment is an apparatus for processing the substrate S in various manners, such as thermal processing of the substrate S or formation of a thin film on the substrate S. For example, the substrate processing apparatus may be a rapid thermal processing (RTP) apparatus that generates high-temperature heat to rapidly thermally process the substrate S. The substrate S may be a silicon wafer used in a semiconductor device or may be a glass substrate applied to a display device such as an LCD or OLED, for example, various target objects for which thermal processing is required.

The chamber 100 may be separated from an external space to provide the processing space in which a substrate is processed, and the chamber 100 may be provided in a box shape. An entrance through which the substrate S is loaded and unloaded may be provided at one side of the chamber 100. Thus, the substrate S may be loaded into and unloaded from the chamber 100 through the entrance, and the substrate S that is completely processed in the chamber 110 may be transferred to the outside of the chamber 100 through the entrance. If necessary, a gas supply part (not shown) that supplies a process gas into the chamber 100 or a plasma generator (not shown) that activates the process gas may be connected.

The substrate support 200 is installed to support the substrate S in an inner space of the chamber 100. The substrate support 200 may be provided to support an edge of a lower portion of the substrate S. Thus, an area of a bottom surface of the substrate S, which does not in contact with the substrate support 200, may be exposed to the inner space of the chamber 100.

The substrate support 200 may be provided in a hollow shape with an opened central portion. Thus, when the substrate S is seated on the substrate support 200, an edge portion of the bottom surface of the substrate S may be in contact with the substrate support 200, and a remaining portion may be exposed downward. In addition, the substrate support 200 may rotate to realize temperature uniformity of the substrate S.

The heater 300 may serve to supply thermal energy to the substrate S and may include a plurality of semiconductor laser modules 310 that irradiates light toward the first face of the substrate. The heater 300 may be disposed to be spaced upward from the substrate support 200 so that the light energy generated by the plurality of semiconductor laser modules 310 provided in the heater 300 is provided to the first face of the substrate S seated on the substrate support 200 to heat the substrate S.

Each of the semiconductor laser modules 310 may provide the light energy for heating the substrate S. The plurality of semiconductor laser modules 310 may be provided and installed in a plurality of mounting grooves, respectively. The plurality of semiconductor laser modules 310 may be disposed to be spaced apart from each other, and an arrangement and installation structure of the plurality of semiconductor laser modules 310 may be variously changed depending on a shape and size of the substrate S.

The semiconductor laser module 310 includes a plurality of semiconductor laser diodes 311 two-dimensionally arranged to form an array. The plurality of semiconductor laser diodes 311 may be provided in the form of one chip or may be provided by mounting a plurality of chips.

The heater 300 may further include a window (not shown) between the processing space of the chamber 100 and the semiconductor laser module 310. The window may serve to transmit light emitted from the semiconductor laser module 310 so that the light energy generated from the semiconductor laser module 310 is provided to the substrate S inside the chamber 100.

One or more pyrometers 400 may be provided at a side of the second face of the substrate (e.g., a lower side of the substrate), which faces the first face, to detect light incident from the substrate S, thereby measuring a temperature. The pyrometer 400 may receive incident radiant light from the substrate to measure a radiant energy or amount of radiated light. Here, the pyrometers 400 may be disposed at a lower side of the substrate S seated on the substrate support 200 to obtain radiant energy and reflectance on areas facing each other so that each of the pyrometers 400 measure a temperature for each area or position of the substrate S at a corresponding position. A process in which the pyrometer 400 measures a temperature using light emitted from an object is widely known using a blackbody radiation theoretical equation, and thus, detailed description thereof will be omitted.

In general, the pyrometer 400 measures the temperature using a wavelength band of approximately 0.9 μm to approximately 1.0 μm, and a temperature measurement region ranges of approximately 400° C. to approximately 1,150° C. However, light transmittance of the substrate with respect to light having a wavelength band of approximately 0.9 μm to approximately 1.0 μm has characteristics dependent on the temperature of the substrate. For example, in the case of the silicon wafer, the silicon wafer has light transmittance in a translucent state at a temperature of approximately 600° C. or less. That is, the silicon wafer has a characteristic of transmitting light in a low-temperature region due to material characteristics thereof, and thus, when the substrate has a low temperature of approximately 600° C. or less, a portion of light of the halogen lamp, which has a wavelength of approximately 0.4 μm to approximately 6.0 μm is transmitted through the substrate. Thus, in the case of the low-temperature substrate, a portion of the light of the halogen lamp having a radiation wavelength of approximately 0.4 μm to approximately 6.0 μm is transmitted through the substrate. As a result, the pyrometer having a measurement wavelength band of approximately 0.9 μm to approximately 1.0 μm may measure the transmitted light, and thus, the temperature of only the substrate may not be accurately measured, and a temperature measurement error may occur.

To solve the above limitation, in the substrate processing apparatus in accordance with an exemplary embodiment, a plurality of semiconductor laser modules 310 having a main emission wavelength less than the measurement wavelength of the pyrometer 400 may be used as a light source.

The semiconductor laser or semiconductor laser diode is a device that emits coherent laser light from a junction when a voltage is applied to both ends of the semiconductor laser or semiconductor laser diode and has a structure in which an active region is inserted between PN junctions to emit light having a wavelength determined by a thickness and composition of the active region. Thus, the semiconductor laser may emit light having a predetermined wavelength by changing the thickness and composition of the active region.

Since the silicon wafer has light transmittance in a translucent state at a temperature of approximately 600° C. or less, light emitted from the plurality of semiconductor laser modules may pass through the silicon wafer to reach the pyrometer 400 like the light emitted from the halogen lamp. However, since the main emission wavelength of the plurality of semiconductor laser modules 310 is less than the measurement wavelength of the pyrometer 400, the light may be excluded from the amount of light measured by the pyrometer, and thus, the amount of light measured by the pyrometer may be measured as an amount of light emitted or reflected from the substrate. For example, when the semiconductor laser module having an emission wavelength of approximately 0.85 μm is used as the light source, even if light passing through the silicon wafer having a temperature of approximately 600° C. or less reaches the pyrometer, since the light has a wavelength out of the wavelength of approximately 0.9 μm to approximately 1.0 μm, which is the measurement wavelength of the pyrometer, the light may be excluded from the amount of light measured by the pyrometer, and thus, an accurate temperature of the substrate may be measured.

In the case of the semiconductor light emitting diode (LED), light having various wavelengths may be emitted by changing the composition of the active region. Here, in the case of the semiconductor light emitting diode, since a spectral width of output light is generally approximately 30 nm to approximately 120 nm, which is relatively wide, it is not suitable because there is a high possibility that a band overlapping approximately 0.9 μm to approximately 1.0 μm, which is the measurement wavelength of the pyrometer 400, is generated. To prevent the wavelength band from overlapping the measurement wavelength band of the pyrometer 400, the emission wavelength of the semiconductor light emitting diode has to be less than that of visible or ultraviolet light, but the shorter wavelength of light is not as effective in transferring the thermal energy rather than infrared light having a wavelength of approximately 850 nm.

On the other hand, in the case of the semiconductor laser (LD), if the semiconductor laser is a single-mode LD, a spectral width of output light may be generally much narrower than 1 nm, and even if the semiconductor laser is a multi-mode LD, output light has a narrow spectral width of approximately 3 nm to approximately 10 nm. Thus, while using the infrared light (e.g., infrared light having a wavelength of approximately 850 nm), a wavelength band of output light that does not overlap the wavelength of approximately 0.9 μm to approximately 1.0 μm, which is the measurement wavelength of the pyrometer 400, may be obtained.

The substrate processing apparatus in accordance with an exemplary embodiment may further include a controller 500 that measures an amount of light incident from the substrate measured by the pyrometer 400 to calculate a temperature and controls power input to the plurality of semiconductor laser modules 310 provided in the heater unit 300 by using the calculated temperature.

The controller 500 may include an output power determination part 510 that determines a power output value by comparing a preset target temperature to the temperature measured by the pyrometer 400 and a power supply 520 that applies power determined by the output power determination part 510 to the plurality of semiconductor laser modules 310 provided in the heater 300. The controller 500 may simultaneously control all of the plurality of semiconductor laser modules 310 in accordance with the measured temperature and individually control or group the plurality of semiconductor laser modules 310 in accordance with the temperature for each area of the substrate S corresponding to the position at which each of the pyrometers 400 is provided to control an operation and the output power of each of the semiconductor laser modules 310.

A temperature at which the substrate S is processed in the substrate processing apparatus in accordance with an exemplary embodiment may include a temperature range of approximately 600° C. or less.

Recently, a new material such as nickel silicide (NiSi) is required to reduce leakage current and resistance of a shallow junction in the latest semiconductor devices such as nano-CMOS, FinFET, and the like. To deposit a thin film such as nickel silicide, a low-temperature process at a temperature of approximately 600° C. or less is essential.

In the case of using the halogen lamp or the semiconductor light emitting diode (LED), which is generally used as the light source for heating, the pyrometer may not accurately measure a temperature in the low-temperature range of approximately 600° C. or less, and thus, a cumbersome process such as additional installation of another component capable of measuring the temperature even in the low-temperature range of approximately 600° C. or less in the substrate processing apparatus is required, and as a result, the structure of the substrate processing apparatus may also be complicated.

On the other hand, the substrate processing apparatus in accordance with an exemplary embodiment may use the plurality of semiconductor laser modules 310 having the main emission wavelength less than the measurement wavelength of the pyrometer 400 as the light source for heating to accurately measure a temperature even at a temperatures of approximately 600° C. or less, and thus, all of processes in a wide temperature range from the low-temperature process of 600° C. or less to a high-temperature process without an additional temperature measurement component may be processed.

The plurality of semiconductor laser modules 310 in accordance with an exemplary embodiment may include a vertical cavity surface emitting laser (VCSEL).

The semiconductor laser diode may be broadly divided into an edge-emitting laser (EEL) and a cavity surface emitting laser in accordance with a light emission manner. The vertical cavity surface emitting laser has a structure in which a beam is emitted in a direction perpendicular to the substrate, unlike the typical side-emitting laser such as a distributed feedback laser diode (DFB LD) or a Fabri-Perot laser diode (FP LD). Since the beam is emitted in the direction perpendicular to the substrate, the beam may have circular symmetry distribution, and thus, light uniformity may be superior to that of the side-emitting laser, and a wafer-scale process and fabrication may be enabled to manufacture a low-cost laser production. Also, since a resonance distance is very short, threshold current may decrease, and the overall output may decrease.

Particularly, a surface light source having a large area has to be provided so as to be used as the light source for heating in the substrate processing apparatus. For this, the laser diode needs to be manufactured as a two-dimensional array type parallel light source. In the case of the side-emitting laser, it is difficult to manufacture the laser diode as the two-dimensional array-type parallel light source because light is emitted through a side surface of a structure laminated on the substrate. However, the vertical cavity surface emitting laser may be manufactured very easily as the two-dimensional array type parallel light source in a desired shape because a structure laminated on the substrate needs to be provided into a desired structure.

In the vertical cavity surface emitting laser, an irradiation angle of the light source is approximately 20 degrees to approximately 25 degrees with respect to a direction perpendicular to the emission surface and thus is very narrow compared to an irradiation angle of approximately 30 degrees to approximately 40 degrees of the light emitting diode (LED). As a result, straightness of light is good. Accordingly, the two-dimensional array type parallel light source capable of irradiating light having a high output and high precision onto the substrate as well as capable of emitting uniform light may be realized.

The vertical cavity surface emitting laser is constituted by a mirror layer+an active layer+a mirror layer on the substrate to emit a vertical beam. For example, in the case of a short wavelength band of approximately 850 nm, GaAs is used as the substrate, and a distributed Bragg reflector (DBR) in which low and high refractive indexes are alternately grown through a change in Al composition of AlGaAs that is lattice-matched to GaAs is used as the mirror layer. In addition, a GaAs multi-quantum well structure that generates light having a desired wavelength is mainly used as the active layer.

The semiconductor laser modules 310 may be provided in parallel to each other so that a distance between the emission surface and the substrate is constant to uniformly heat the substrate, which is an object to be heated. Thus, each of the semiconductor laser modules 310 needs to be configured as the surface light source having a size corresponding to the size of the substrate. For this, the plurality of semiconductor laser modules 310 in which the vertical cavity surface emitting lasers are arranged in the two-dimensional array may be provided to correspond to the size of the substrate.

The plurality of semiconductor laser modules 310 may include a central semiconductor laser module provided at a central portion of the heater and a peripheral semiconductor laser module provided around the central semiconductor laser module.

In the substrate processing apparatus, the substrate may rotate to realize the temperature uniformity of the substrate. When being heated using the light energy emitted from the light source, a central portion of the substrate serves as a center of rotation, and thus, overlapping of the light energy may occur at the central portion of the substrate. As a result, temperatures at the central portion and the edge of the substrate may be non-uniform. Thus, it is necessary to differently control light energy emitted from a central portion and an edge of the heater, which correspond to the central portion and the edge portion of the substrate.

Accordingly, in the plurality of semiconductor laser modules 310, a central semiconductor laser module 310a provided at a central portion of the heater and peripheral semiconductor lasers 310b to 310g module provided around the central semiconductor laser module 310a may be arranged. In the case of the peripheral semiconductor laser module, the central semiconductor laser module 310a may be provided in the form of multiple wrapping, such as a double shell or a triple shell that defines concentric circles, depending on the size and shape of the substrate. Power applied to the central semiconductor laser module 310a and the peripheral semiconductor laser modules 310b to 310g may be independently controlled to realize the temperature uniformity of the substrate. In the case of the peripheral semiconductor laser module constituting the multi-shell, the applied power may be selectively controlled for each group by grouping the shells. Here, the pyrometer may be provided on a substrate area corresponding to the grouped semiconductor laser module to measure a temperature of the substrate area, thereby feeding the measured temperature back to the controller. Also, the grouped shells may be regrouped to be controlled into a regrouped unit.

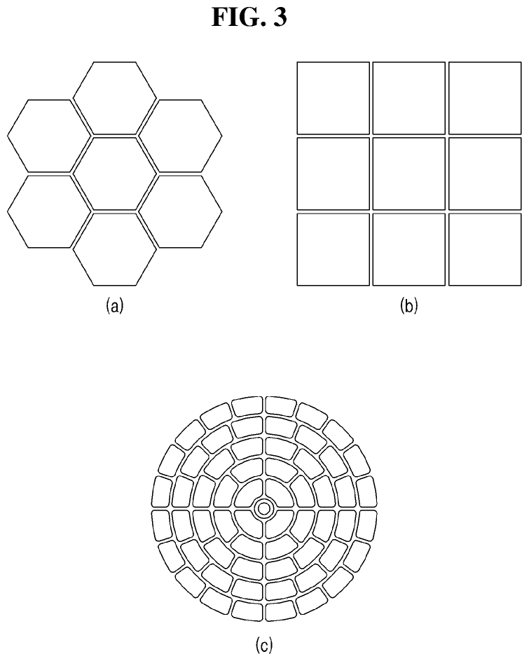

FIG. 3 is a view illustrating various shapes of an arrangement of the semiconductor laser modules in accordance with an exemplary embodiment.

As illustrated in FIG. 3, the shape of the semiconductor laser module 310 may be variously changed into a hexagon shape, a square shape, an arc shape, etc., and the arrangement may also be variously adopted in accordance with the shape of the semiconductor laser module 310. Here, the shape or arrangement of the semiconductor laser module 310 is sufficient as long as the substrate is heated to a uniform temperature.

Each of the plurality of semiconductor laser modules 310 may have an edge having a polygonal shape.

The semiconductor laser modules may be arranged in various manners in accordance with the size and shape of the substrate, and thus, a size of the entire semiconductor laser module assembly needs to be expanded. When the plurality of semiconductor laser modules are arranged, a spaced distance inevitably occurs between the semiconductor laser modules, and since there is no light emission at the spaced distance, a light emission state and temperature distribution, which are different from those in the semiconductor laser module may be inevitably exhibited. Therefore, it is necessary to two-dimensionally constantly maintain the spaced distance between the semiconductor laser modules. If the edge of the semiconductor laser module has the polygonal shape, the semiconductor laser modules may be adjacent to each other using the edges (line segments) of the semiconductor laser modules to secure a uniform spaced distance on the emission surface of the entire heater. On the other hand, when circular semiconductor laser modules are two-dimensionally arranged, spaced distances are inevitably different from each other in accordance with directions.

In addition, a planar light source assembly may be provided by simply assembling the modules on a plane only when the plurality of semiconductor laser modules that need to be expanded in accordance with to the shape and size of the substrate have the same shape.

In the case of the substrate processing apparatus, which processes the semiconductor wafer, it is preferable in terms of temperature uniformity of the substrate when an outer shape of the heater 300 and the plurality of semiconductor laser modules approximate a circular shape according to a shape of the wafer. Here, if the edge of the semiconductor laser module is provided in a hexagonal shape, the semiconductor laser module may be easily expanded to match the size and shape of the substrate while uniformly maintaining the spaced distance as a whole. For example, a heater corresponding to a 4-inch wafer may be configured as seven hexagonal semiconductor laser modules, and a heater corresponding to a 12-inch wafer may be configured as 61 hexagonal semiconductor laser modules.

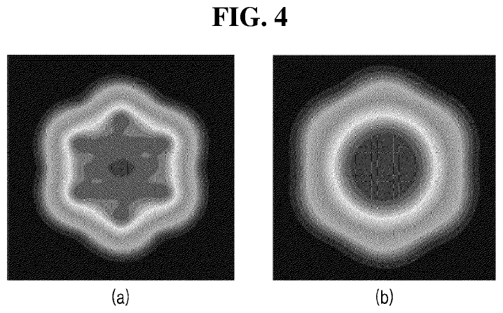

FIG. 4 is a view illustrating an effect of the temperature uniformity of the substrate processing apparatus in accordance with an exemplary embodiment, wherein (a) of FIG. 4 illustrates a temperature distribution simulation result when an LED light source is used as a comparative example, and (b) of FIG. 4 illustrates a temperature distribution simulation result when a VCSEL light source is used as an exemplary embodiment. Specifically, (b) of FIG. 4 illustrates a temperature distribution result when a light source (center honeycomb structure) in which a semiconductor laser module having a hexagonal edge as illustrated in FIG. 2 is arranged in the form of the central semiconductor laser module 310a and the peripheral semiconductor laser modules 310b to 310g.

In the case of the LED light source as the comparative example, the light irradiation angle is wide to approximately 30 degrees to approximately 40 degrees, and also, a width of the emission spectrum is wide. On the other hand, in the case of the VCSEL light source having the center honeycomb structure, which corresponds to an exemplary embodiment, the light irradiation angle is very narrow to approximately 20 degrees to approximately 25 degrees, and thus, straightness of light is good, and a width of the emission spectrum is also very narrow. Due to this properties, a two-dimensional array type parallel light source capable of irradiating light having a high output and high precision onto the substrate as well as capable of emitting uniform light may be realized. Thus, it is seen that, in the comparative example, the temperature distribution is very non-uniform for each area, whereas, in the exemplary embodiment, the temperature distribution is uniform at the central portion having a considerably wide area and also is uniform along a radius even at the edge.

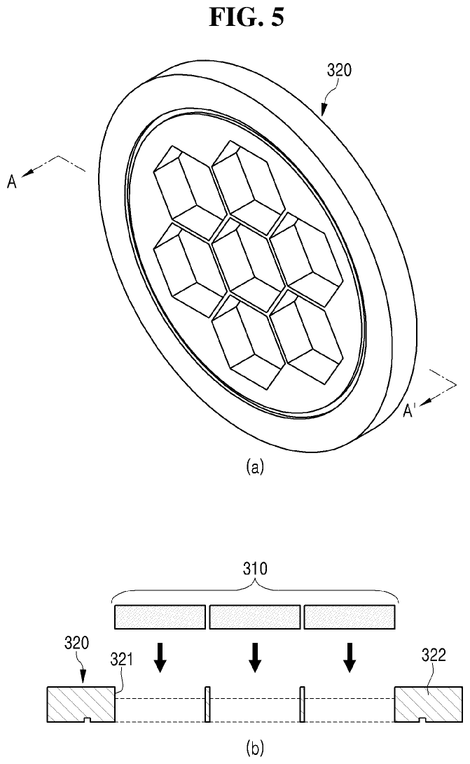

FIG. 5 is a view illustrating a reflector in accordance with an exemplary embodiment, wherein (a) of FIG. 5 is a perspective view of the reflector, and (b) of FIG. 5 is a cross-sectional view taken along line A-A′.

Referring to FIG. 5, the substrate processing apparatus in accordance with an exemplary embodiment may further include a reflector 320 surrounding the edge of each of the plurality of semiconductor laser modules 310 to reflect at least a portion of light emitted from the plurality of semiconductor laser modules 310 toward the substrate S.

A semiconductor laser 311 has superior light straightness compared to the light emitting diode (LED), but does not emit light completely perpendicular to the emission surface and has an irradiation angle of approximately 20 degrees to approximately 25 degrees. Thus, a portion of the light emitted from the semiconductor laser may not be incident to the substrate at a high angle. Therefore, light efficiency may be maximized by reflecting diffused light among the light emitted from the semiconductor laser module using the reflector 320 toward the substrate.

The reflector 320 may be provided in a plate shape and have a concave portion or through-portion into which each of the semiconductor laser modules is inserted and mounted and may include a side surface, which defines the concave portion or the through-portion and is inclined with respect to the emission surface of each of the semiconductor laser modules, and a front surface, which is connected to the side surface and is parallel to the emission surface of the semiconductor laser module. The side surface of the reflector 320 may provide an inclined reflective surface 321 that reflects the light emitted from the semiconductor laser module to reflect the diffused light toward the substrate, and the front surface of the reflector 320 may provide a front reflective surface 322 that reflects a portion of the light emitted from the semiconductor laser module toward the substrate and then reflects the light incident to the heater again toward the substrate.

The inclined reflective surface 321 may be provided to form an inclination angle of approximately 80 degrees to approximately 90 degrees with respect to the emission surface of the semiconductor laser module.

Since the semiconductor laser diode has an irradiation angle (or radiation angle) of approximately 20 degrees to approximately 25 degrees with respect to a direction perpendicular to the emission surface, the inclination angle of the inclined reflective surface has to form an angle of approximately 80 degrees to approximately 90 degrees with respect to the emission surface to effectively reflect the diffused light toward the substrate. Light having an irradiation angle (or radiation angle) of approximately 20 degrees to approximately 25 degrees on the inclined reflective surface having the inclination angle of approximately 80 degrees to approximately 90 degrees may be obliquely incident to the inclined reflective surface and then be reflected and focused onto the substrate so as to be incident at a high angle. On the other hand, in the case of the light emitting diode (LED), since light having an irradiation angle of approximately 30 degrees to approximately 40 degrees with respect to the direction perpendicular to the emission surface is incident to the inclined reflective surface at a high angle, the light may be obliquely incident to the substrate at a low angle and then reflected again, and thus, the light energy may not be efficiently transmitted to the substrate.

When the inclined reflective surface 321 forms an inclined angle less than approximately 80 degrees with respect to the emission surface of the semiconductor laser module, the light emitted from the semiconductor laser having good optical straightness may not be irradiated to the inclined reflective surface and thus may be directed to the substrate as it is at the high angle. Thus, the light may not be incident at the high angle to deteriorate the light uniformity. On the other hand, when the inclined reflective surface 321 forms an inclination angle greater than approximately 90 degrees with respect to the emission surface of the semiconductor laser module, since the inclined reflective surface faces the semiconductor laser module, the reflected light may be directed again to the semiconductor laser module, resulting in optical loss.

A metal reflective film may be coated on the inclined reflective surface 321 and/or the front reflective surface 322 to more improve reflection efficiency. A body of the reflector 320 may be made of an aluminum alloy having good thermal conductivity and good mechanical strength, and the inclined reflective surface 321 and/or the front reflective surface 322 may provide a mirror surface through polishing. Thus, due to the polishing, since a fine structure still exists in a surface that causes diffuse reflection, the metal reflective film may be coated to more improve the reflection efficiency. The metal reflective film may be gold (Au), aluminum (Al), or the like, but it is not necessary to be particularly limited to the material, and it is sufficient as long as the metal reflective film is made of a metal material that is stable at a high temperature and performs mirror reflection.

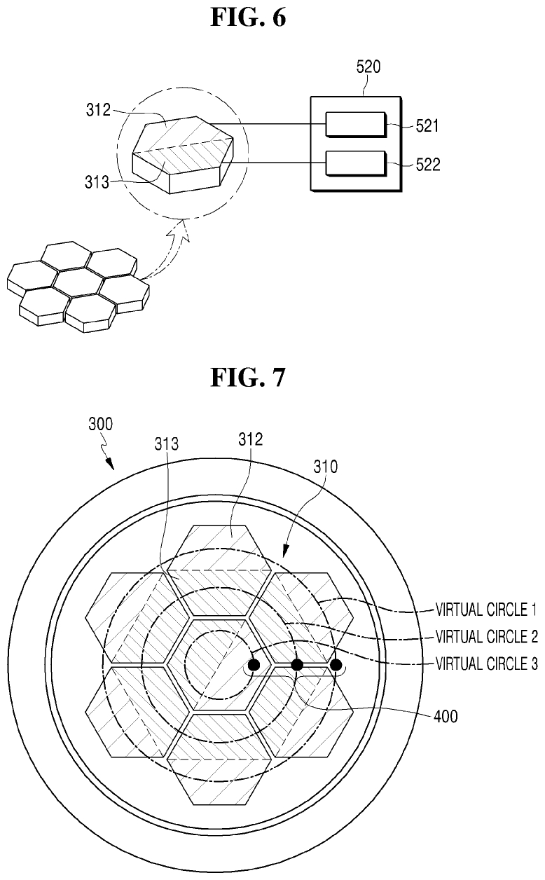

FIG. 6 is a view for explaining a manner for controlling the semiconductor laser module in accordance with an exemplary embodiment, and FIG. 7 is a view for explaining a manner for arranging the semiconductor laser module in accordance with an exemplary embodiment.

Referring to FIGS. 6 to 7, in the substrate processing apparatus in accordance with an exemplary embodiment, each of the plurality of semiconductor laser modules 310 may be divided into a first area 312 and a second area 313, and the plurality of first areas 312 and the plurality of second areas 313 may be electrically connected for each area. In addition, the substrate processing apparatus in accordance with an exemplary embodiment may further include a first power supply 521 and a second power supply 522, which independently apply power applied respectively for each area to the plurality of first areas 312 electrically connected to each other and the plurality of second areas 313 electrically connected to each other.

The plurality of semiconductor laser modules 310 may be arranged in a two-dimensional array in accordance with the shape and size of the substrate. In the plurality of semiconductor laser modules 310 arranged in the two-dimensional array, the applied power may be controlled individually for each module or for each grouped group. When the semiconductor laser module is provided into one light source unit and controlled individually or grouped, a power supply or controller such as a SMPS (switched mode power supply) has to be connected to each module, resulting in a very complicated structure and cumbersome control process.

Therefore, in an exemplary embodiment, each of the semiconductor laser modules may be divided into the plurality of areas including the first area 312 and the second area 313, and the plurality of first areas 312 and the plurality of second areas 313 may be electrically connected for each area so as to be grouped. The power input for each area may be independently applied to the plurality of first areas 312 electrically connected to each other and the plurality of second areas 313 electrically connected to each other by using the first power supply 521 and the second power supply 522 to control a temperature for each area of the heater 300 or each area of the substrate, thereby improving the temperature uniformity.

That is, the semiconductor laser module may be divided into the plurality of areas including the first area 312 and the second area 313, which have the same structure, and the plurality of semiconductor laser modules may be arranged in the two-dimensional array in various shapes and sizes as necessary and be independently controlled for each area to realize the substrate processing apparatus, which has a simple structure.

Since the first area and the second area provided in the plurality of semiconductor laser modules are grouped and controlled in the same manner, it is necessary to measure temperatures corresponding to the first area and the second area so as to control the applied power. Thus, the pyrometer 400 may include a first pyrometer provided to correspond to the first area and a second pyrometer provided to correspond to the second area. The first pyrometer may be provided at a substrate lower side of a substrate area that receives light irradiated by the first area group of the semiconductor laser module, and the second pyrometer may be provided at a substrate lower side of a substrate area that receives light irradiated by the second area group of the semiconductor laser module to measure each temperature. The first power supply 521 and the second power supply 522 may apply power to each area of the plurality of semiconductor modules, i.e., the first area group and the second area group, which are divided, by using the temperatures measured from the first pyrometer and the second pyrometer.

The plurality of semiconductor laser modules may be arranged so that at least one virtual circle centered at the center of the heater 300 crosses either one of the first area and the second area. For example, in FIG. 7, the plurality of semiconductor laser modules may be arranged so that a virtual circle 2 crosses only the second area 313 of the semiconductor laser module, and the plurality of semiconductor laser modules may be arranged so that a virtual circle 3 crosses only the first area 312 of the semiconductor laser module. When the hexagonal semiconductor laser modules have the center honeycomb structure in which the central semiconductor laser module 310a and the peripheral semiconductor laser modules 310b to 310g are arranged, if the first area and the second area of each of the peripheral semiconductor laser modules are radially arranged in the same order and toward the center with respect to the central semiconductor laser module 310a, at least one virtual circle using the center of the heater 300 as a center thereof may cross only any one of the first area and the second area.

In accordance with the arrangement of the plurality of semiconductor laser modules, in the case of the substrate rotating for temperature uniformity, a substrate area (e.g., an area corresponding to a virtual line of FIG. 7) corresponding to the same radius from the center point of the heater may cross the same area (the first area or the second area) of the plurality of semiconductor laser modules.

In the case of the plurality of semiconductor laser modules having the center honeycomb structure, the pyrometer and the second pyrometer may be respectively provided at a position (corresponding to a virtual line 3) crossing only the plurality of first areas and a position (corresponding to a virtual line 2) crossing only the plurality of second areas to measure the temperature for each area. Additionally, if the third pyrometer is provided at a substrate lower side (e.g., the virtual circle 1) of the substrate area corresponding to the central semiconductor laser module, the substrate area (central portion of the substrate) corresponding to the central semiconductor laser module may continuously cross the first area and the second area of the central semiconductor laser module while rotating to measure a mean temperature of the substrate corresponding to the first area and the second area.

Since the third pyrometer measures the mean temperature of the first area and the second area, the mean temperature may correspond to a predetermined process temperature (i.e., substrate processing temperature). When the temperature non-uniformity is confirmed based on the temperatures measured by the first pyrometer and the second pyrometer while controlling the heater or the plurality of semiconductor laser modules as a whole based on the temperature measured by the third pyrometer, the first power supply 521 and the second power supply 522 may individually apply power to the first areas (or the first area group) and the second areas (or the second area group) by using the temperatures measured by the first pyrometer and the second pyrometer. If the temperature non-uniformity is not confirmed based on the temperatures measured by the first to second pyrometers, the first power supply 521 and the second power supply 522 may apply the same power to the first area and the second area.

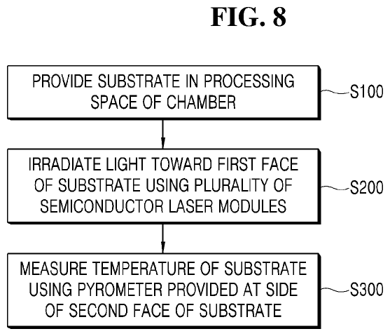

FIG. 8 is a flowchart illustrating a substrate processing method in accordance with another exemplary embodiment. In description of a substrate processing method according to another exemplary embodiment, matters overlapping those described above with respect to the substrate processing apparatus in accordance with an exemplary embodiment will be omitted.

Referring to FIG. 8, a substrate processing method in accordance with another exemplary embodiment may include a process (S100) of providing a substrate in a processing space of a chamber, a process (S200) of irradiating light onto a first face of the substrate by using a plurality of semiconductor laser modules provided in a heater, and a process (S300) of measuring a temperature of the substrate by using a pyrometer provided at a side of a second face of the substrate, which faces the first face, and a main emission wavelength of the plurality of semiconductor laser modules may be less than a measurement wavelength of the pyrometer. Here, a temperature at which the substrate is processed may include a temperature range of approximately 600° C. or less.

Each of the processes of the substrate processing method in accordance with another exemplary embodiment may not be necessarily performed in a time-series order, and if necessary, each of the processes may be performed in a reverse order or may be performed simultaneously. For example, after the process (S300) of measuring the temperature of the substrate, the process (S200) of irradiating the light onto the first face of the substrate may be performed.

First, the substrate may be provided in the processing space of the chamber (see S100). Thereafter, the substrate processing method may further include a process of providing the substrate to the processing space of the chamber and then supplying various process gases or active species generated by a remote plasma generator into the processing space.

Next, the light may be irradiated onto the first face of the substrate by using the plurality of semiconductor laser modules 310 provided in the heater 300 provided on the first face of the substrate (see S200). Light energy of the light emitted from the plurality of semiconductor laser modules 310 may be irradiated to the substrate, and thus, the light energy may be converted into thermal energy to increase in temperature of the substrate. Here, the light energy of the light emitted from the plurality of semiconductor laser modules 310 may be determined in accordance with an amount of power applied to the semiconductor laser module by a controller 500.

In addition, the temperature of the substrate may be measured using the pyrometer 400 provided at a side of the second face of the substrate, which faces the first face (see S300). The pyrometer 400 may measure the temperature using radiant energy of the light incident from the substrate.

In general, the pyrometer 400 measures the temperature using a wavelength band of approximately 0.9 μm to approximately 1.0 μm, and a temperature measurement region ranges of approximately 400° C. to approximately 1,150° C. However, light transmittance of the substrate with respect to light having a wavelength band of approximately 0.9 μm to approximately 1.0 μm has characteristics dependent on the temperature of the substrate. For example, in the case of the silicon wafer, the silicon wafer has light transmittance in a translucent state at a temperature of approximately 600° C. or less. That is, the silicon wafer has a characteristic of transmitting light in a low-temperature region due to material characteristics thereof, and thus, when the substrate has a low temperature of approximately 600° C. or less, a portion of light of the halogen lamp, which has a wavelength of approximately 0.4 μm to approximately 6.0 μm is transmitted through the substrate. Thus, in the case of the low-temperature substrate, a portion of the light of the halogen lamp having a radiation wavelength of approximately 0.4 μm to approximately 6.0 μm is transmitted through the substrate. As a result, the pyrometer having a measurement wavelength band of approximately 0.9 μm to approximately 1.0 μm may measure the transmitted light, and thus, the temperature of only the substrate may not be accurately measured, and a temperature measurement error may occur.

Therefore, in the substrate processing method in accordance with another exemplary embodiment, the main emission wavelength of the plurality of semiconductor laser modules 310 that irradiate the light onto the first face of the substrate in the process (S200) may be less than the measurement wavelengths of the pyrometer 400 that measures the temperature of the substrate in the process (S300).

Since the silicon wafer has light transmittance in a translucent state at a temperature of approximately 600° C. or less, light emitted from the plurality of semiconductor laser modules may pass through the silicon wafer to reach the pyrometer 400 like the light emitted from the halogen lamp. However, since the main emission wavelength of the plurality of semiconductor laser modules 310 is less than the measurement wavelength of the pyrometer 400, the light may be excluded from the light measured by the pyrometer, and thus, the light measured by the pyrometer may be measured as a light emitted or reflected from the substrate. For example, when the semiconductor laser module having an emission wavelength of approximately 0.85 μm is used as the light source, even if light passing through the silicon wafer having a temperature of approximately 600° C. or less reaches the pyrometer, since the light has a wavelength out of the wavelength of approximately 0.9 μm to approximately 1.0um, which is the measurement wavelength of the pyrometer, the light may be excluded from the radiation energy or the amount of light measured by the pyrometer, and thus, an accurate temperature of the substrate may be measured.

Recently, a new material such as nickel silicide (NiSi) is required to reduce leakage current and resistance of a shallow junction in the latest semiconductor devices such as nano-CMOS, FinFET, and the like. To deposit a thin film such as nickel silicide, a low-temperature process at a temperature of approximately 600° C. or less is essential. In the substrate processing method in accordance with another exemplary embodiment, the plurality of semiconductor laser modules 310 having the main emission wavelength less than the measurement wavelength of the pyrometer 400 may be used as the light source for heating to accurately measure a temperature even at a temperatures of approximately 600° C. or less, and thus, all of processes in a wide temperature range from the low-temperature process of 600° C. or less to a high-temperature process without an additional temperature measurement component may be processed.

The plurality of semiconductor laser modules irradiating the light onto the substrate may include a vertical cavity surface emitting laser.

The vertical cavity surface emitting laser has a structure in which a beam is emitted in a direction perpendicular to the substrate, unlike the typical side emitting laser. Since the beam is emitted in the direction perpendicular to the substrate, the beam may have circular symmetry distribution, and thus, light uniformity may be superior to that of the side-emitting laser, and a wafer-scale process and fabrication may be enabled to manufacture a low-cost laser production. Also, since a resonance distance is very short, threshold current may decrease, and the overall output may decrease.

Particularly, a surface light source having a large area has to be provided so as to be used as the light source for heating in the substrate processing apparatus. For this, the laser diode needs to be manufactured as a two-dimensional array type parallel light source. In the case of the side-emitting laser, it is difficult to manufacture the laser diode as the two-dimensional array-type parallel light source because light is emitted through a side surface of a structure laminated on the substrate. However, the vertical cavity surface emitting laser may be manufactured very easily as the two-dimensional array type parallel light source in a desired shape because a structure laminated on the substrate needs to be provided into a desired structure.

In the vertical cavity surface emitting laser, an irradiation angle of the light source is approximately 20 degrees to approximately 25 degrees with respect to a direction perpendicular to the emission surface and thus is very narrow compared to an irradiation angle of approximately 30 degrees to approximately 40 degrees of the light emitting diode (LED). As a result, straightness of light is good. Accordingly, the two-dimensional array type parallel light source capable of irradiating light having a high output and high precision onto the substrate as well as capable of emitting uniform light may be realized.

Each of the plurality of semiconductor laser modules may be divided into a first area and a second area, and the plurality of first areas and the plurality of second areas may be electrically connected for each area. The process (S200) of irradiating the light may include a process (S210) of applying the power independently to the plurality of first areas electrically connected to each other and the plurality of second areas electrically connected to each other for each area.

Each of the semiconductor laser modules 310 may be divided into the plurality of areas including the first area 312 and the second area 313, and the plurality of first areas 312 and the plurality of second areas 313 may be electrically connected for each area so as to be grouped. The power may be independently applied to the plurality of first areas 312 electrically connected to each other and the plurality of second areas 313 electrically connected to each other by using the first power supply 521 and the second power supply 522 to control a temperature for each area of the heater 300 or each area of the substrate, thereby improving the temperature uniformity. That is, the semiconductor laser module may be divided into the plurality of areas including the first area 312 and the second area 313, which have the same structure, and the plurality of semiconductor laser modules may be arranged in the two-dimensional array in various shapes and sizes as necessary and be independently controlled for each area to realize the substrate processing method through simple processes.

Since the first area and the second area provided in the plurality of semiconductor laser modules are grouped and controlled in the same manner, it is necessary to measure temperatures corresponding to the first area and the second area so as to control the applied power. Thus, the pyrometer 400 may include a first pyrometer provided to correspond to the first area and a second pyrometer provided to correspond to the second area.

The process (S300) of measuring the temperature of the substrate may include a process of measuring the temperature for each area on the areas of the substrate corresponding to the first area and the second area by using the first pyrometer and the second pyrometer, and in the process (S210) of applying the power, the power may be independently applied to each area using the measured temperature for each area.

The plurality of semiconductor laser modules may be arranged so that at least one virtual circle centered at the center of the heater 300 crosses either one of the first area and the second area. In accordance with the arrangement of the plurality of semiconductor laser modules, in the case of the substrate rotating for temperature uniformity, a substrate area (e.g., an area corresponding to a virtual line of FIG. 7) corresponding to the same radius from the center point of the heater may cross the same area (the first area or the second area) of the plurality of semiconductor laser modules.

In the case of the plurality of semiconductor laser modules having the center honeycomb structure, the pyrometer and the second pyrometer may be respectively provided at a position (corresponding to a virtual line 3) crossing only the plurality of first areas and a position (corresponding to a virtual line 2) crossing only the plurality of second areas to measure the temperature for each area. Additionally, if the third pyrometer is provided at a substrate lower side (e.g., the virtual circle 1) of the substrate area corresponding to the central semiconductor laser module, the substrate area (central portion of the substrate) corresponding to the central semiconductor laser module may continuously cross the first area and the second area of the central semiconductor laser module while rotating to measure a mean temperature of the substrate corresponding to the first area and the second area.

The process (S300) of measuring the temperature of the substrate may further include a process of measuring a mean temperature of the first area and the second area using the third pyrometer. The mean temperature of the first area and the second area may correspond to a preset process temperature (i.e., a substrate processing temperature).

The process (S200) of irradiating the light may include a process of applying the power to all of the plurality of semiconductor laser modules using the temperature measured by the third pyrometer and a process of determining temperature non-uniformity based on the temperature measured by the first to second pyrometers.

The same power may be applied to the first areas (or the first area group) and the second areas (or the second area group) in the process of controlling the power to all of the plurality of semiconductor laser modules.

When the temperature non-uniformity is confirmed in the process of determining the temperature non-uniformity, a process of applying the power independently to the first areas (or the first area group) and the second areas (or the second area group) from the first power supply 521 and the second power supply 522 by using the temperatures measured by the first pyrometer and the second pyrometer may be performed. If the temperature non-uniformity is not confirmed in the process of determining the temperature non-uniformity, the first power supply 521 and the second power supply 522 may continuously apply the same power to the first area and the second area.

In the substrate processing apparatus and the substrate processing method in accordance with the exemplary embodiments, since the light energy is supplied using the semiconductor laser module having the main emission wavelength band that is different from the measurement wavelength band of the pyrometer, the temperature of the substrate may be accurately measured and controlled even in the low-temperature region of approximately 600° C. or less.

In addition, in the apparatus and method for measuring the temperature of the substrate in accordance with the embodiments, the temperature of the substrate in a low-temperature region of approximately 600° C. or less may be accurately calculated, and the power applied to the heater may be controlled based on the calculated substrate temperature to precisely control the temperature of the substrate in the low-temperature region and secure the temperature uniformity of the substrate, thereby preventing the substrate from being damaged and securing reliability of the low-temperature process that is performed at a temperature of approximately 600° C. or less.

When the vertical cavity surface emitting laser is used as the light source, the power consumption may be reduced compared to the typical halogen lamp and the light emitting diode (LED) due to the high energy efficiency, and the light characteristics may be effectively controlled due to the straightness of the light source and the easy emission of the light having the specific wavelength.

In addition, the semiconductor laser module may be divided into the plurality of regions and arranged in the various types of arrays, and the input power may be controlled for each area to correspond to the substrates having the various sizes and shapes and improve the uniformity of the temperature control of the substrate and the variability of the process tuning.

The meaning of “on” as used in the above description includes cases in direct contact and cases in which direct contact is not made but an object is located opposite to the upper or bottom surface, and it is possible not only to be positioned to face the upper surface or the bottom surface as a whole, but also to face partially the upper surface or the bottom surface. And it is used to mean that the object is positioned away from the upper surface or the bottom surface and faces to the upper surface or the bottom surface, or the object directly contacts the upper surface or the bottom surface.

Although embodiments have been described with reference to a number of illustrative embodiments thereof, the embodiments are not limited to the foregoing embodiments, and thus, it should be understood that numerous other modifications and embodiments can be devised by those skilled in the art that will fall within the spirit and scope of the principles of this disclosure. Hence, the real protective scope of the present inventive concept shall be determined by the technical scope of the accompanying claims.

1. A substrate processing apparatus comprising:
a chamber configured to provide a processing space in which a substrate is processed;
a substrate support provided in the processing space of the chamber to support the substrate;
a heater provided with a plurality of semiconductor laser modules configured to irradiate light toward a first face of the substrate; and
a pyrometer provided at a side of a second face facing the first face to detect light incident from the substrate, thereby measuring a temperature,
wherein a main emission wavelength of the plurality of semiconductor laser modules is less than a measurement wavelength of the pyrometer.

2. The substrate processing apparatus of claim 1, wherein a temperature at which the substrate is processed comprises a temperature range of approximately 600° C. or less.

3. The substrate processing apparatus of claim 1, wherein each of the semiconductor laser modules comprises a vertical cavity surface emitting laser.

4. The substrate processing apparatus of claim 1, wherein the plurality of semiconductor laser modules comprise:
a central semiconductor laser module provided at a central portion of the heater; and
a peripheral semiconductor laser module provided around the central semiconductor laser module.

5. The substrate processing apparatus of claim 1, wherein each of the plurality of semiconductor laser modules has an edge having a polygonal shape.

6. The substrate processing apparatus of claim 1, further comprising a reflector configured to surround an edge of each of the plurality of semiconductor laser modules to reflect at least a portion of light emitted from the plurality of semiconductor laser modules toward the substrate.

7. The substrate processing apparatus of claim 6, wherein the reflector comprises an inclined reflective surface having an inclined angle of approximately 80 degrees to approximately 90 degrees with respect to an emission surface of each of the plurality of semiconductor laser modules.

8. The substrate processing apparatus of claim 7, wherein a metal reflective film is coated on the inclined reflective surface.

9. The substrate processing apparatus of claim 1, wherein each of the plurality of semiconductor laser modules is divided into a first area and a second area, wherein the plurality of first areas and the plurality of second areas are electrically connected for each area, and
the substrate processing apparatus further comprises a first power supply and a second power supply, which independently apply power applied respectively for each area to the plurality of first areas electrically connected to each other and the plurality of second areas electrically connected to each other.

10. The substrate processing apparatus of claim 9, wherein the pyrometer comprises:
a first pyrometer provided to correspond to the first area; and
a second pyrometer provided to correspond to the second area,
wherein the first power supply and the second power supply are configured to apply the power to the plurality of semiconductor modules for each area using temperatures measured by the first pyrometer and the second pyrometer.

11. The substrate processing apparatus of claim 9, wherein the plurality of semiconductor laser modules are arranged so that at least one virtual circle using a central portion of the heater as a center crosses either one of the first area and the second area.

12. A substrate processing method comprising:
providing a substrate in a processing space of a chamber;
irradiating light onto a first face of the substrate by using a plurality of semiconductor laser modules provided in a heater; and
measuring a temperature of the substrate by using a pyrometer provided at a side of a second face of the substrate, which faces the first face,
wherein a main emission wavelength of the plurality of semiconductor laser modules is less than a measurement wavelength of the pyrometer.

13. The substrate processing method of claim 12, wherein a temperature at which the substrate is processed comprises a temperature range of approximately 600° C. or less.

14. The substrate processing method of claim 12, wherein each of the semiconductor laser modules comprises a vertical cavity surface emitting laser.

15. The substrate processing method of claim 12, wherein each of the plurality of semiconductor laser modules is divided into a first area and a second area, wherein the plurality of first areas and the plurality of second areas are electrically connected for each area, and
the irradiating of the light comprises applying power independently for each area to the plurality of first areas electrically connected to each other and the plurality of second areas electrically connected to each other.

16. The substrate processing method of claim 15, wherein the pyrometer comprises:
a first pyrometer provided to correspond to the first area; and
a second pyrometer provided to correspond to the second area,
wherein the measuring of the temperature comprises measuring a temperature for each area on areas of the substrate, which correspond to the first area and the second area, by using the first pyrometer and the second pyrometer, and
in the applying of the power, the power is independently applied for each area by using the measured temperature for each area.

17. The substrate processing method of claim 15, wherein the plurality of semiconductor laser modules are arranged so that at least one virtual circle using a central portion of the heater as a center crosses either one of the first area and the second area.
